(19) United States
(12) Patent Application Publication
(10) Pub. No.: US 2008/0074208 A1
(43) Pub. Date: Mar. 27, 2008

(54) DEVICE AND METHOD OF TWO-POINT MODULATION

(76) Inventor: Kun-Seok Lee, Seoul (KR)

Correspondence Address: F. CHAU & ASSOCIATES, LLC, 130 WOODBURY ROAD, WOODBURY, NY, 11797, US

(21) Appl. No.: 11/856,452

(22) Filed: Sep. 17, 2007

(30) Foreign Application Priority Data
Sep. 25, 2006 (KR) 2006-92634

(51) Int. Cl. H03C 3/09

(52) U.S. Cl. 332/127; 341/143

(57) ABSTRACT

A two-point modulation device includes a first sigma-delta modulator (SDM), a second SDM and an analog phase-locked loop (PLL). The first SDM provides a division control signal based on channel data and modulation data. The second SDM provides a feedforward path modulation signal based on the modulation data. The analog PLL receives the division control signal and the feedforward path modulation signal, and generates a voltage-controlled oscillating frequency signal that follows a reference frequency signal.

### CROSS-REFERENCE TO RELATED APPLICATIONS

This application claims priority under 35 USC § 119 to Korean Patent Application No. 2006-92634, filed on Sep. 25, 2006 in the Korean Intellectual Property Office (KIPO), the disclosure of which is incorporated by reference herein in its entirety.

### BACKGROUND OF THE INVENTION

1. Technical Field

The present disclosure relates to wireless mobile communication, and more particularly to a device and a method of two-point modulation and a two-point modulation circuit for wireless mobile communication.

2. Discussion of Related Art

Two-point modulation may be implemented by two methods. In a first method, both a feedback path and a feedforward path are digitally implemented using a digitally controlled oscillator (DCO). However, the frequency resolution of the DCO needs to satisfy the frequency resolution of a carrier frequency. This may require that tens of Hz be tunable, for example, in a Global System for Mobile Communications (GSM). The frequency resolution of a DCO may also vary considerably.

In a second method, a digital-to-analog converter (DAC) and a low-pass filter (LPF) are employed in a feedforward path by using an analog phase-locked loop (PLL) and a voltage-controlled oscillator VCO. However, chip size may increase significantly as the resolution of the DAC increases. In addition, performance may be degraded and the chip size may increase when the feedforward path is combined with a feedback path.

FIG. 1 is a block diagram of a conventional two-point modulator. Referring to FIG. 1, the two-point modulator 5 includes a phase-locked loop (PLL) that includes a phase/frequency detector (PFD) 10, a loop filter 20, a voltage-controlled oscillator (VCO) 30, and a divider 40. The two-point modulator 5 further includes a sigma-delta modulator (SDM) 50, a digital-to-analog converter (DAC) 60, a low-pass filter (LPF) 70, and an adder 80.

The SDM 50 receives channel data CH and modulation data MOD. An output signal of the SDM 50 is provided to the divider 40, and is used for dividing an output frequency Fout of the VCO 30. The DAC 60 converts the modulation data MOD to an analog signal to be provided to the LPF 70. The LPF 70 filters an output signal of the DAC 60, and provides the filtered output signal to the adder 80. The loop filter 20 receives an output signal of the PFD 10 that detects a phase/frequency difference between a reference frequency Fref and the divided output frequency, and provides the output signal of the PFD 10 to the adder 80. The adder 80 sums the output signal of the loop filter 20 and the output signal of the LPF 70, and provides the summed output signal to the VCO 30. The VCO 30 provides the output frequency Fout in response to the output signal of the adder 80.

However, the size of the DAC 60 occupies a large area and system characteristics can be degraded when the feedback path and the feedforward path are combined.

Accordingly, there is a need for a system and method of performing two-point modulation that reduces degradation of system characteristics without increasing chip size when a feedback path and a feedforward path are combined.

### SUMMARY OF THE INVENTION

In an exemplary embodiment of the present invention, a two-point modulation device includes a first sigma-delta modulator (SDM), a second SDM and an analog phase-locked loop (PLL). The first SDM provides a division control signal based on channel data and modulation data. The second SDM provides a feedforward path modulation signal based on the modulation data. The analog PLL receives the division control signal and the feedforward path modulation signal, and generates a voltage-controlled oscillating frequency signal that follows a reference frequency signal.

The analog PLL may include a divider, a phase/frequency detector (PFD), a charge pump, a loop filter, and a voltage-controlled oscillator (VCO). The divider divides the voltage-controlled oscillating frequency signal based on the division control signal. The PFD detects a phase/frequency difference between a reference frequency signal and the divided voltage-controlled oscillating frequency signal. The charge pump generates a current signal based on the detected phase/frequency difference. The loop filter low-pass filters the current signal to generate a control voltage. The VCO receives the feedforward path modulation signal, and generates the voltage-controlled oscillating frequency signal that oscillates in response to the control voltage.

The division control signal may be a digital signal. The feedforward path modulation signal may be a digital signal. The VCO may simultaneously perform analog feedback path tuning and digital feedforward path tuning. A frequency resolution of the voltage-controlled oscillating frequency signal may be controlled by the analog PLL. A frequency resolution of the modulation data may be controlled by the second SDM.

In an exemplary embodiment of the present invention, a method of two-point modulation includes providing a division control signal based on channel data and modulation data, providing a feedforward path modulation signal based on the modulation data, generating a voltage-controlled oscillating frequency signal that follows a reference frequency signal based on the division control signal and the feedforward path modulation signal.

The voltage-controlled oscillating frequency signal may be generated by steps of dividing the voltage-controlled oscillating frequency signal based on the division control signal, detecting a phase/frequency difference between a reference frequency signal and the divided voltage-controlled oscillating frequency signal, generating a current signal based on the detected phase/frequency difference, low-pass filtering the current signal to provide a control voltage, and receiving the feedforward path modulation signal to generate the voltage-controlled oscillating frequency signal that oscillates in response to control voltage.

The division control signal and the feedforward path modulation signal may be digital signals. The voltage-controlled oscillating frequency signal may be generated based on analog feedback path tuning and digital feedforward path tuning that are simultaneously performed.

A frequency resolution of the voltage-controlled oscillating frequency signal may be controlled by generating the voltage-controlled oscillating frequency signal. A frequency resolution of the modulation data may be controlled by providing the feedforward path modulation signal.

In an exemplary embodiment of the present invention, a two-point modulation circuit includes a first SDM, a second SDM, an analog PLL, and a VCO gain control unit. The first SDM provides a division control signal based on channel data and modulation data. The second SDM provides a feedforward path modulation signal based on the modulation data and a VCO gain control signal. The analog PLL receives the division control signal and the feedforward path modulation signal, and generates a voltage-controlled oscillating frequency signal that follows a reference frequency signal. The VCO gain control unit provides the VCO gain control signal based on a reference frequency signal and the voltage-controlled oscillating frequency signal. The division control signal, the feedforward path modulation signal, and the VCO gain control signal may be digital signals.

In an exemplary embodiment of the present invention, a two-point modulation-based transceiver includes a first SDM, a second SDM, an analog PLL, a frequency synthesizer, a demodulator, and a frequency multiplier. The first SDM provides a division control signal based on channel data and modulation data. The second SDM provides a feedforward path modulation signal based on the modulation data. The analog PLL receives the division control signal and the feedforward path modulation signal, and generates a voltage-controlled oscillating frequency signal that follows a reference frequency signal provided from a reference frequency generator. The frequency synthesizer down-converts the voltage-controlled oscillating frequency signal to provide an intermediate frequency signal. The demodulator demodulates the intermediated frequency signal and provides a demodulation signal. The frequency multiplier multiplies the reference frequency signal and provides a multiplied reference frequency signal to the frequency synthesizer.

### BRIEF DESCRIPTION OF THE DRAWINGS

FIG. 1 is a block diagram illustrating an example of a conventional two-point modulator.

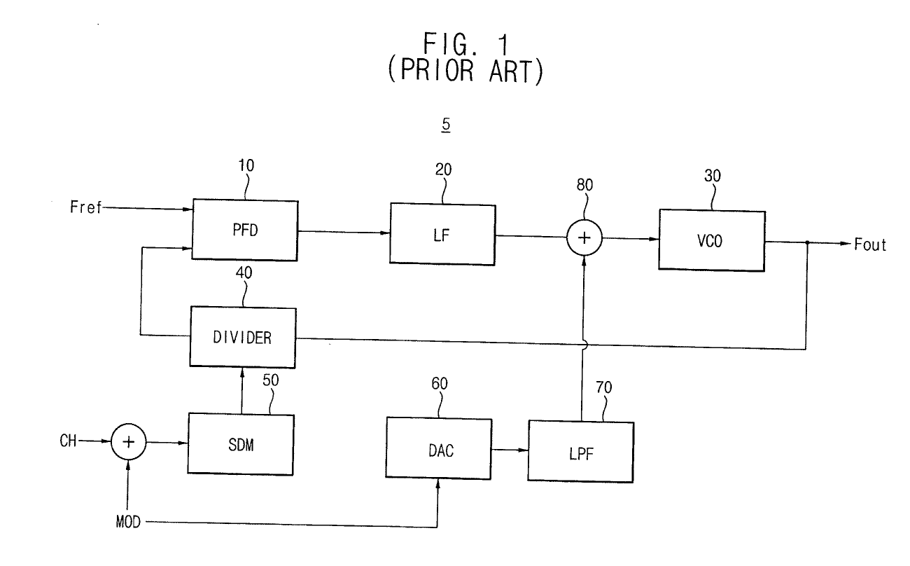

FIG. 2 is a block diagram illustrating a two-point modulation device according to an exemplary embodiment of the present invention.

FIG. 3 is a circuit diagram illustrating the second sigma-delta modulator (SDM) in FIG. 2.

FIG. 4 is a flow chart illustrating a method of two-point modulation according to an exemplary embodiment of the present invention.

FIG. 5 is a flow chart illustrating a process of generating a voltage-controlled oscillating frequency signal in FIG. 4.

FIG. 6 is a block diagram illustrating a two-point modulation circuit according to an exemplary embodiment of the present invention.

FIG. 7 is a block diagram illustrating a two-point modulation-based transceiver according to an exemplary embodiment of the present invention.

### DETAILED DESCRIPTION OF EXEMPLARY EMBODIMENTS

Exemplary embodiments of the present invention will now be described more fully with reference to the accompanying drawings. The present invention may, however, be embodied in many different forms and should not be construed as limited to the exemplary embodiments set forth herein. Like reference numerals refer to like elements throughout this application.

It will be understood that when an element is referred to as being “connected” or “coupled” to another element, it can be directly connected or coupled to the other element or intervening elements may be present.

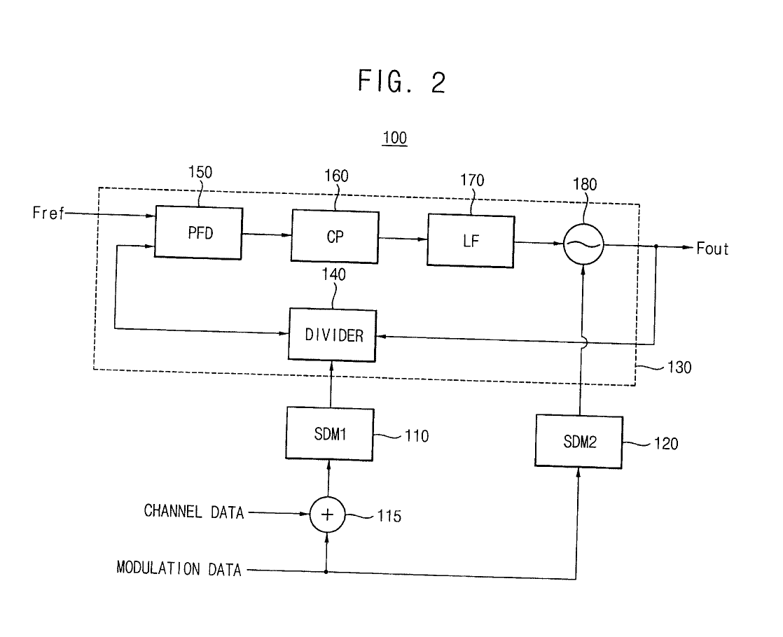

FIG. 2 is a block diagram illustrating a two-point modulation device according to an exemplary embodiment of the present invention. Referring to FIG. 2, the two-point modulation device 100 includes a first SDM 110, a second SDM 120, and an analog PLL 130. The first SDM 110 receives channel data and modulation data to provide a division control signal. An adder 115, which combines the channel data and the modulation data, may be included in the first SDM 110. The second SDM 120 receives the modulation data to provide a feedforward path modulation signal. The division control signal and the feedforward path modulation signal may be digital signals.

The analog PLL 130 may include a divider 140, a PFD 150, a charge pump 160, a loop filter 170, and a VCO 180. The divider 140 divides a voltage-controlled oscillating frequency signal Fout provided from the VCO 180 in response to the division control signal from the first SDM 110, and provides the divided voltage-controlled oscillating frequency signal Fout to the PFD 150. The PFD 150 receives a reference frequency signal Fref and the divided voltage-controlled oscillating frequency signal Fout, and detects a phase/frequency difference between the reference signal Fref and the divided voltage-controlled oscillating frequency signal Fout. The charge pump 160 generates a current signal for charging or discharging the loop filter 170 according to an output signal of the PFD 150. The loop filter 170 performs low-pass filtering on an output signal of the charge pump 160. The VCO 180 receives the feedforward path modulation signal and generates the voltage-controlled oscillating frequency signal Fout that oscillates in response to an output signal of the loop filter 170. The VCO may simultaneously perform analog tuning and digital tuning. The analog tuning may be performed based on the output signal provided from the loop filter 170, and the digital tuning may be performed based on the feedforward path modulation signal provided from the second SDM 120. A frequency resolution of the carrier frequency may be controlled by the analog PLL 130, and a frequency resolution of the modulation data may be controlled by the feedforward modulation signal that has a relatively broad margin.

The two-point modulation device 100 may be implemented using a relatively small chip size and system characteristics may be degraded less when the feedback path and the feedforward path are combined. In addition, the two-point modulation device 100 may be used as a frequency synthesizer in a receiver if the feedforward path including the second SDM 120 is deactivated.

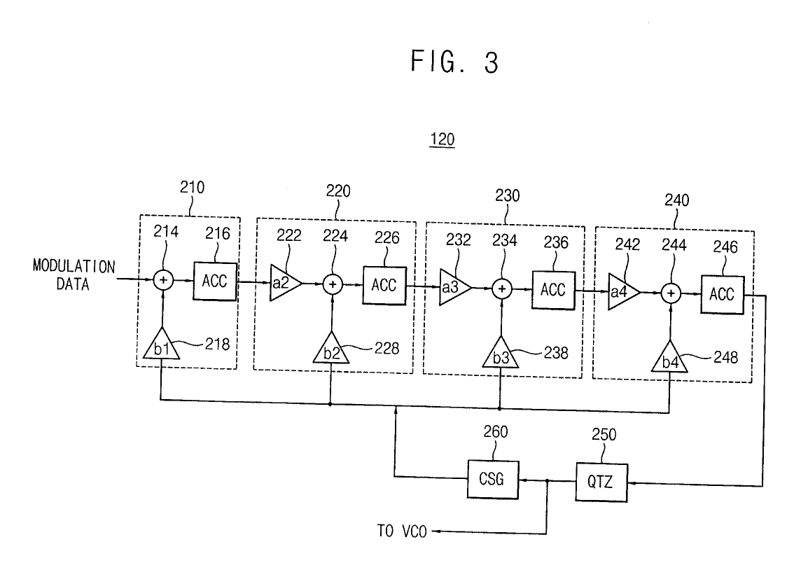

FIG. 3 is a circuit diagram illustrating the second SDM in FIG. 2. The second SDM 120 may be implemented with a fourth-order 3-bit modulator as illustrated in FIG. 3. Referring to FIG. 3, the second SDM 120 includes first through fourth sigma-delta modulation units 210, 220, 230, and 240, a quantizer 250, and a control signal generator 260. The first sigma-delta modulation unit includes an adder 214, an accumulator 216, and a feedback coefficient provider 218. The second, third and fourth sigma-delta modulation units 220, 230 and 240 include adders 224, 234 and 244, accumulators 226, 236 and 246, feedback coefficient providers 228, 238 and 248, and weighted coefficient providers 222, 232 and 242, respectively. The sigma-delta modulation units 210, 220, 230 and 240 perform a sigma-delta modulation based on the multi-bit (e.g., 3-bit) modulation data and the feedback coefficients (b1, b2, b3 and b4). The quantizer 250 quantizes the output signal of the fourth sigma-delta modulation unit 240, and provides the quantized signal to the control signal generator 260. The control signal generator 260 generates a control signal, which is fed back to the feedback coefficient providers 218, 228, 238 and 248 respectively included in the sigma-delta modulation units 210, 220, 230 and 240.

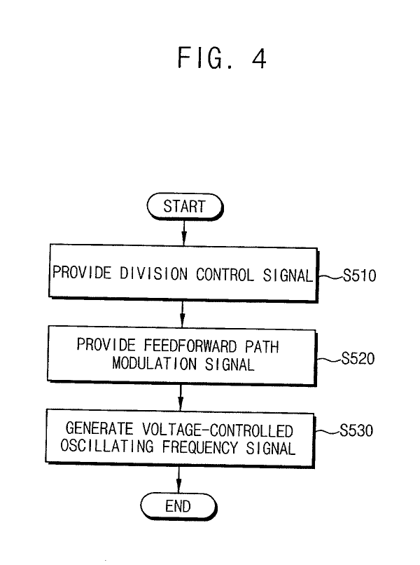

FIG. 4 is a flow chart illustrating a method of two-point modulation according to an exemplary embodiment of the present invention. Referring to FIG. 4, in the method of two-point modulation, a division control signal is provided based on channel data and modulation data (step S510). A feedforward path modulation signal is provided based on the modulation data (step S520). A frequency resolution of the modulation data may be controlled in step S520. The division control signal and the feedforward path modulation signal may be digital signals. A voltage-controlled oscillating frequency signal that follows a reference frequency signal is generated based on the division control signal and the feedforward path modulation signal (step S530). A frequency resolution of the voltage-controlled oscillating frequency signal may be controlled in step S530.

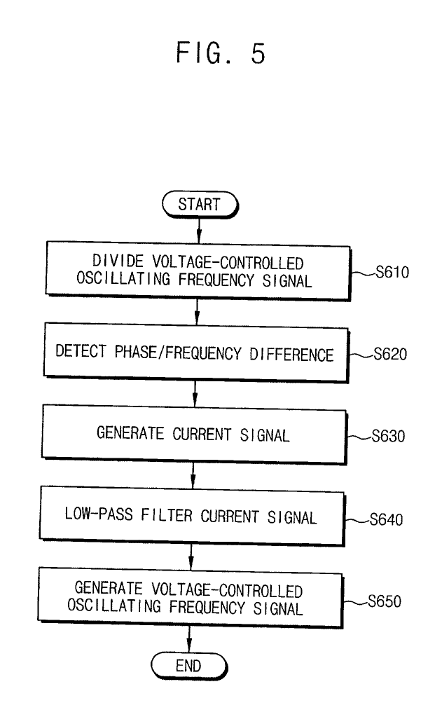

FIG. 5 is a flow chart illustrating the process of generating a voltage-controlled oscillating frequency signal in FIG. 4. Referring to FIG. 5, the voltage-controlled oscillating frequency signal may be generated by the following steps. The voltage-controlled oscillating frequency signal is divided based on the division control signal (step S610). A phase/frequency difference between a reference frequency signal and the divided voltage-controlled oscillating frequency signal is detected (step S620). A current signal is generated based on the detected phase/frequency difference (step S630). The current signal is low-pass filtered to provide a control voltage (step S640). The feedforward path modulation signal is received and the voltage-controlled oscillating frequency signal that oscillates in response to the control voltage is generated (step S650).

The operations as described with reference to FIGS. 4 and 5 may be performed by using the two-point modulation device in FIGS. 2 and 3.

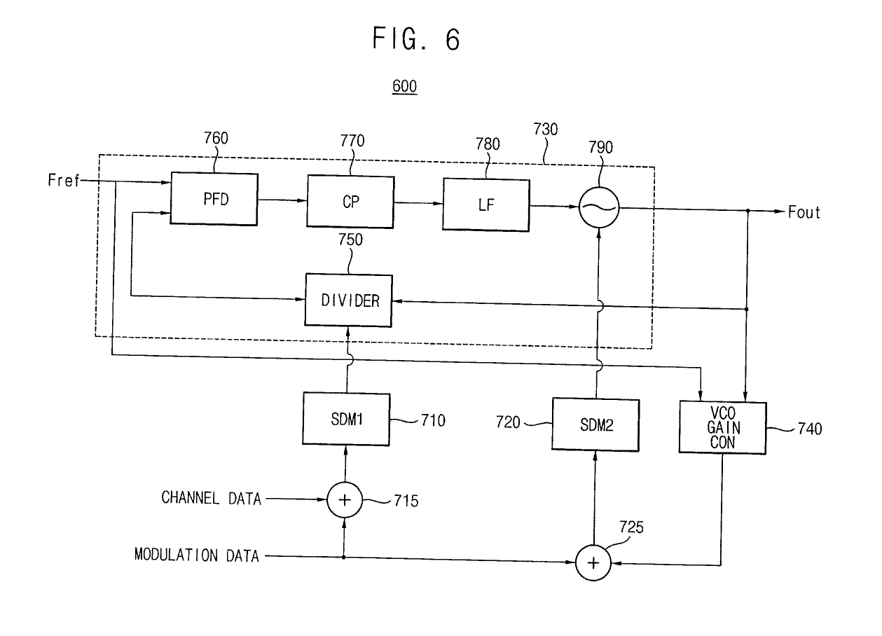

FIG. 6 is a block diagram illustrating a two-point modulation circuit according to an exemplary embodiment of the present invention. Referring to FIG. 6, a two-point modulation circuit 600 includes a first SDM 710, a second SDM 720, an analog PLL 730, and a VCO gain control unit 740. The analog PLL includes a divider 750, a PFD 760, a charge pump 770, a loop filter 780, and a VCO 790.

The first SDM 710 receives combined channel data and modulation data, and provides a division control signal to the divider 750. An adder 715, which combines the channel data and the modulation data, may be included in the first SDM 710. The division control signal may be a digital signal.

The second SDM 720 receives combined modulation data and a VCO gain control signal as an output signal of the VCO gain control unit 740, and provides a feedforward path modulation signal to the VCO 790. An adder 725, which combines the modulation data and the VCO gain control signal, may be included in the second SDM 720. The feedforward path modulation signal may be a digital signal. A gain of the VCO 790 may be controlled by using digital codes. The VCO gain control unit 740 receives a reference frequency signal Fref and a voltage-controlled oscillating frequency signal Fout, and provides the VCO gain control signal to the second SDM 740.

Operations of the divider 750, the PFD 760, the charge pump 770, the loop filter 780, and the VCO 790 in FIG. 6 are substantially the same as operations of the divider 140, the PFD 150, the charge pump 160, the loop filter 170, and the VCO 180 in FIG. 2.

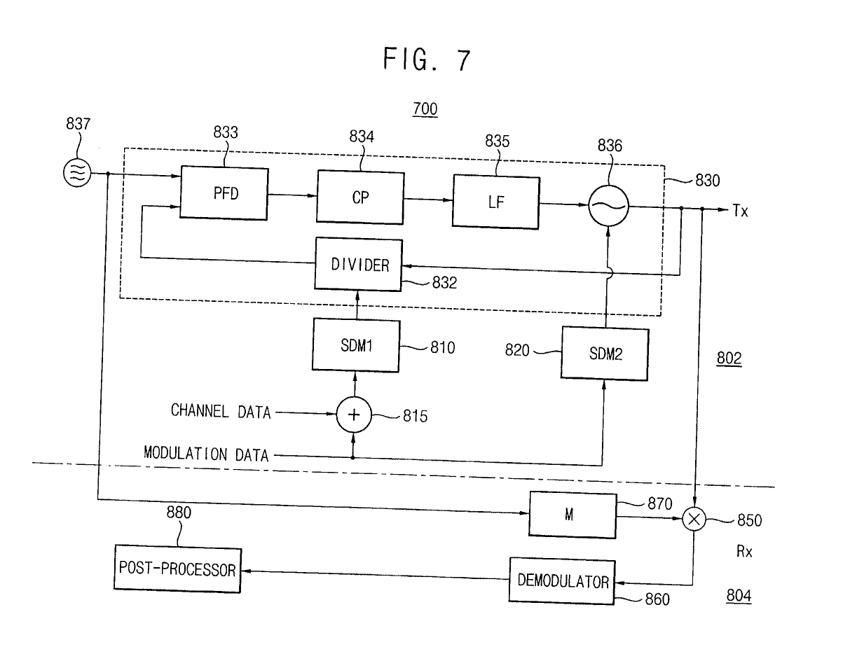

FIG. 7 is a block diagram illustrating a two-point modulation-based transceiver according to an exemplary embodiment of the present invention.

Referring to FIG. 7, the two-point modulation-based transceiver 700 includes a transmitter unit 802 and a receiver unit 804. The transmitter unit 802 includes a first SDM 810, a second SDM 820 and an analog PLL 830. The analog PLL includes a divider 832, a PFD 833, a charge pump 834, a loop filter 835, and a VCO 836. A reference frequency generator 837 may be included in the transmitter unit 802. The reference frequency generator 837 generates a reference frequency. The operation and circuit structure of the transmitter unit 830 are similar with those of the two-point modulation device 100 in FIG. 2.

The receiver unit 804 includes a frequency synthesizer 850, a demodulator 860, a frequency multiplier 870, and a post-processor 880. The frequency synthesizer 850 down-converts the voltage-controlled oscillating frequency signal to provide an intermediate frequency signal. The demodulator 860 demodulates the intermediate frequency signal to provide a demodulation signal (i.e., a demodulated intermediate frequency signal) to the post-processor 880. The post-processor 880 processes the demodulation signal to a baseband signal. The frequency multiplier 870 multiplies the reference frequency signal by a predetermined factor M, and provides a multiplied reference frequency signal to the frequency synthesizer 850.

While exemplary embodiments of the present invention have been described in detail, it should be understood that various changes, substitutions and alterations may be made herein without departing from the scope of the invention.

What is claimed is:

1. A two-point modulation device, comprising:
a first sigma-delta modulator (SDM) configured to provide a division control signal based on channel data and modulation data;
a second SDM configured to provide a feedforward path modulation signal based on the modulation data; and
an analog phase-locked loop (PLL) that receives the division control signal and the feedforward path modulation signal, the analog PLL configured to generate a voltage-controlled oscillating frequency signal that follows a reference frequency signal.

2. The two-point modulation device of claim 1, wherein the analog PLL comprises:
a divider that divides the voltage-controlled oscillating frequency signal based on the division control signal;
a phase/frequency detector (PFD) that detects a phase/frequency difference between a reference frequency signal and the divided voltage-controlled oscillating frequency signal;
a charge pump that generates a current signal based on the detected phase/frequency difference;
a loop filter that low-pass filters the current signal to provide a control voltage; and
a voltage-controlled oscillator (VCO) that receives the feedforward path modulation signal, the VCO configured to generate the voltage-controlled oscillating frequency signal that oscillates in response to the control voltage.

3. The two-point modulation device of claim 1, wherein the division control signal is a digital signal.

4. The two-point modulation device of claim 1, wherein the feedforward path modulation signal is a digital signal.

5. The two-point modulation device of claim 2, wherein the VCO simultaneously performs analog feedback path tuning and digital feedforward path tuning.

6. The two-point modulation device of claim 5, wherein a frequency resolution of the voltage-controlled oscillating frequency signal is controlled by the analog PLL.

7. The two-point modulation device of claim 5, wherein a frequency resolution of the modulation data is controlled by the second SDM.

8. A method of two-point modulation, the method comprising:
providing a division control signal based on channel data and modulation data;
providing a feedforward path modulation signal based on the modulation data; and
generating a voltage-controlled oscillating frequency signal that follows a reference frequency signal based on the division control signal and the feedforward path modulation signal.

9. The method of claim 8, wherein generating the voltage-controlled oscillating frequency signal comprises:
dividing the voltage-controlled oscillating frequency signal based on the division control signal;
detecting a phase/frequency difference between the reference frequency signal and the divided voltage-controlled oscillating frequency signal;
generating a current signal based on the detected phase/frequency difference;
low-pass filtering the current signal to provide a control voltage; and
receiving the feedforward path modulation signal to generate the voltage-controlled oscillating frequency signal that oscillates in response to the control voltage.

10. The method of claim 8, wherein the division control signal and the feedforward path modulation signal are digital signals.

11. The method of claim 10, wherein the voltage-controlled oscillating frequency signal is generated based on analog feedback path tuning and digital feedforward path tuning that are simultaneously performed.

12. The method of claim 11, wherein a frequency resolution of the voltage-controlled oscillating frequency signal is controlled by generating the voltage-controlled oscillating frequency signal.

13. The method of claim 11, wherein a frequency resolution of the modulation data is controlled by providing the feedforward path modulation signal.

14. A two-point modulation circuit comprising:
a first sigma-delta modulator (SDM) configured to provide a division control signal based on channel data and modulation data;
a second SDM configured to provide a feedforward path modulation signal based on the modulation data and a (voltage-controlled oscillator) VCO gain control signal;
an analog phase-locked loop (PLL) that receives the division control signal and the feedforward path modulation signal, the analog PLL configured to generate a voltage-controlled oscillating frequency signal that follows a reference frequency signal; and
a VCO gain control unit configured to provide the VCO gain control signal based on a reference frequency signal and the voltage-controlled oscillating frequency signal.

15. The two-point modulation circuit of claim 14, wherein the analog PLL comprises:
a divider that divides the voltage-controlled oscillating frequency signal based on the division control signal;
a phase/frequency detector (PFD) that detects a phase/frequency difference between the reference frequency signal and the divided voltage-controlled oscillating frequency signal;
a charge pump that generates a current signal based on the detected phase/frequency difference;
a loop filter that low-pass filters the current signal to provide a control voltage; and
a VCO that receives the feedforward path modulation signal, and the VCO configured to generate the voltage-controlled oscillating frequency signal that oscillates in response to the current voltage.

16. The two-point modulation circuit of claim 14, wherein the division control signal, the feedforward path modulation signal and the VCO gain control signal are digital signals.

17. The two-point modulation circuit of claim 16, wherein the VCO simultaneously performs analog feedback path tuning and digital feedforward path tuning.

18. The two-point modulation circuit of claim 17, wherein a frequency resolution of the voltage-controlled oscillating frequency signal is controlled by the analog PLL.

19. The two-point modulation circuit of claim 17, wherein a frequency resolution of the modulation data is controlled by the second SDM.

20. A two-point modulation-based transceiver comprises:
a first sigma-delta modulator (SDM) configured to provide a division control signal based on channel data and modulation data;
a second SDM configured to provide a feedforward path modulation signal based on the modulation data;
an analog phase-locked loop (PLL) that receives the division control signal and the feedforward path modulation signal, the analog PLL configured to generate a voltage-controlled oscillating frequency signal that follows a reference frequency signal provided from a reference frequency generator;
a frequency synthesizer that down-converts the voltage-controlled oscillating frequency signal to provide an intermediate frequency signal;
a demodulator that demodulates the intermediate frequency signal to provide a demodulation signal; and
a frequency multiplier that multiplies the reference frequency signal and provides a multiplied reference frequency signal to the frequency synthesizer.

21. The two-point modulation-based transceiver of claim 20, wherein the analog PLL comprises:
a divider that divides the voltage-controlled oscillating frequency signal based on the division control signal;
a phase/frequency detector (PFD) that detects a phase/frequency difference between the reference frequency signal and the divided voltage-controlled oscillating frequency signal;
a charge pump that generates a current signal based on the detected phase/frequency difference;
a loop filter that low-pass filters the current signal to provide a control voltage; and
a voltage-controlled oscillator (VCO) that receives the feedforward path modulation signal, the VCO configured to generate the voltage-controlled oscillating frequency signal that oscillates in response to the control voltage.

22. The two-point modulation-based transceiver of claim 20, wherein the division control signal and the feedforward path modulation signal are digital signals.
